(19) United States
(12) Patent Application Publication
(10) Pub. No.: US 2026/0201227 A1
(43) Pub. Date: Jul. 16, 2026

(54) POLISHING LIQUID, POLISHING LIQUID SET AND POLISHING METHOD

(71) Applicant: Resonac Corporation, Tokyo (JP)

(72) Inventors: Satoshi FURUKAWA, Minato-ku, Tokyo (JP); Takaaki MATSUMOTO, Minato-ku, Tokyo (JP)

(21) Appl. No.: 18/860,045

(22) PCT Filed: Aug. 8, 2023
(86) PCT No.: PCT/JP2023/028988

§ 371 Date: Oct. 25, 2024

(30) Foreign Application Priority Data
Aug. 9, 2022 (JP) 2022-127001

(51) Int. Cl. C09K 3/14; H10P 52/40

(52) U.S. Cl. CPC C09K 3/1463; H10P 52/402

(57) ABSTRACT

A polishing liquid contains abrasive grains; an ether compound having at least one selected from the group consisting of a carboxy group and a carboxylate group; and water. A polishing liquid set contains constituent components of the polishing liquid separately stored in a first liquid and a second liquid, in which the first liquid contains abrasive grains and water, and the second liquid contains an ether compound having at least one selected from the group consisting of a carboxy group and a carboxylate group and water. A polishing method includes a step of polishing a surface to be polished containing silicon oxide using the polishing liquid.

### TECHNICAL FIELD

The present disclosure relates to a polishing liquid, a polishing liquid set, a polishing method, and the like.

### BACKGROUND ART

In recent years, a processing technique for densification and miniaturization are becoming more important in manufacturing steps for semiconductor elements. A chemical mechanical polishing (CMIP) technique that is one of the processing techniques has become an essential technique in manufacturing steps for semiconductor elements, for formation of a shallow trench isolation (hereinafter, referred to as “STI”), flattening of pre-metal insulating materials or interlayer insulating materials, formation of plugs or embedded metal wirings, or the like. As a CIP polishing liquid, a CIP polishing liquid containing abrasive grains containing cerium oxide is known (see, for example, Patent Literatures 1 and 2).

### CITATION LIST

### Patent Literature

Patent Literature 1: Japanese Unexamined Patent Publication No. H10-106994
Patent Literature 2: Japanese Unexamined Patent Publication No. H08-022970

### SUMMARY OF INVENTION

### Technical Problem

There is a case where it is required to polish a member (insulating member) containing silicon oxide using a CMP polishing liquid containing abrasive grains to make a surface to be polished smooth. In a finish polishing step, in order to prevent the member containing silicon oxide from being excessively polished, there is a case where it is required to reduce a polishing rate for silicon oxide.

According to an aspect of the present disclosure, an object of the present disclosure is to provide a polishing liquid and a polishing liquid set that can reduce a polishing rate for silicon oxide. In addition, according to another aspect of the present disclosure, an object of the present disclosure is to provide a polishing method using the polishing liquid or the polishing liquid set.

### Solution to Problem

The present disclosure relates to the following [1] to [10] and the like in some aspects.
[1] A polishing liquid containing: abrasive grains; an ether compound having at least one selected from the group consisting of a carboxy group and a carboxylate group; and water.
[2] The polishing liquid according to [1], in which the abrasive grains contain cerium oxide.
[3] The polishing liquid according to [1] or [2], in which the ether compound includes a compound represented by the following General Formula (1):

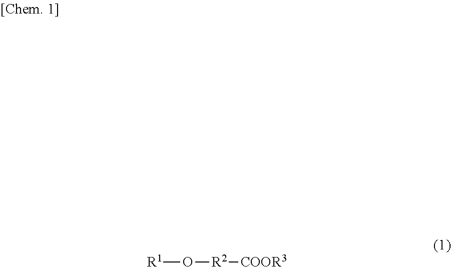

[in Formula (1), R¹ represents an alkyl group having 1 to 10 carbon atoms, R² represents an alkylene group having 1 to 10 carbon atoms, and R³ represents a hydrogen atom or a monovalent metal atom].
[4] The polishing liquid according to any one of [1] to [3], in which the ether compound includes at least one selected from the group consisting of ethoxyacetic acid, methoxyacetic acid, and salts thereof.
[5] The polishing liquid according to any one of [1] to [4], in which a content of the ether compound is less than 0.10 mass % based on a total mass of the polishing liquid.
[6] The polishing liquid according to any one of [1] to [5], in which a pH is 2.0 to 5.0.
[7] The polishing liquid according to any one of [1] to [6], in which the polishing liquid is used for polishing a surface to be polished containing silicon oxide.
[8] A polishing liquid set containing constituent components of the polishing liquid according to any one of [1] to [7] separately stored in a first liquid and a second liquid, in which the first liquid contains the abrasive grains and water, and the second liquid contains the ether compound and water.
[9] A polishing method including a step of polishing a surface to be polished containing silicon oxide using the polishing liquid according to any one of [1] to [7].
[10] A polishing method including a step of polishing a surface to be polished containing silicon oxide using a polishing liquid obtained by mixing the first liquid and the second liquid in the polishing liquid set according to [8].

### Advantageous Effects of Invention

According to an aspect of the present disclosure, it is possible to provide a polishing liquid and a polishing liquid set that can reduce a polishing rate for silicon oxide. In addition, according to another aspect of the present disclosure, it is possible to provide a polishing method using the polishing liquid.

### DESCRIPTION OF EMBODIMENTS

Hereinafter, embodiments of the present disclosure will be described.

In the present specification, a numerical range indicated using “to” indicates a range including numerical values described before and after “to” as a minimum value and a maximum value, respectively. “A or more” of the numerical range means A and a range exceeding A. “A or less” of the numerical range means A and a range less than A. In the numerical range described in stages in the present specification, an upper limit value or a lower limit value of a numerical range of a certain stage can be arbitrarily combined with an upper limit value or a lower limit value of a numerical range of another stage. In the numerical range described in the present specification, the upper limit value or the lower limit value of the numerical range may be replaced with a value shown in Examples. “A or B” may include either A or B, or may include both A and B. The materials exemplified in the present specification can be used alone or in combination of two or more thereof unless otherwise specified. When a plurality of materials corresponding to the respective components are present in the composition, a content of each component in the composition means the total amount of the plurality of materials present in the composition unless otherwise specified. The term “step” includes not only an independent step but also a step that cannot be clearly distinguished from other steps as long as the intended action of the step is achieved.

A polishing liquid according to the present embodiment contains abrasive grains; an ether compound having at least one selected from the group consisting of a carboxy group and a carboxylate group; and water. The polishing liquid according to the present embodiment can be used as, for example, a CMP polishing liquid.

According to the polishing liquid according to the present embodiment, a polishing rate for silicon oxide can be reduced, and for example, the polishing rate for silicon oxide can be set to 400 nm/min or less. The polishing rate for silicon oxide may be 300 nm/min or less, 200 nm/min or less, 100 nm/min or less, 80 nm/min or less, 50 nm/min or less, or 40 nm/min or less.

According to the polishing liquid according to the present embodiment, a polishing rate for silicon nitride can be reduced, and for example, the polishing rate for silicon nitride can be set to 70 nm/min or less. The polishing rate for silicon nitride may be 50 nm/min or less, 30 nm/min or less, 20 nm/min or less, 10 nm/min or less, or 5 nm/min or less.

According to the polishing liquid according to the present embodiment, silicon oxide can be selectively polished with respect to silicon nitride. A polishing rate ratio of silicon oxide to silicon nitride may be 8 or more, 10 or more, 12 or more, 15 or more, 30 or more, 50 or more, or 100 or more. The polishing rate ratio of silicon oxide to silicon nitride may be 200 or less, 150 or less, 100 or less, 75 or less, 50 or less, or 30 or less.

### (Abrasive Grains)

The polishing liquid according to the present embodiment contains abrasive grains. In the present specification, “abrasive grains” mean an aggregate of a plurality of particles, and for convenience, one particle constituting the abrasive grains may be referred to as an abrasive grain. The abrasive grains may contain one or a plurality of kinds of particles. Examples of a constituent material of the abrasive grains of the abrasive grains include inorganic substances such as cerium oxide (ceria), cerium hydroxide, silica, alumina, zirconia, titania, germania, and silicon carbide; and organic substances such as polystyrene, polyacrylic acid, and polyvinyl chloride. The abrasive grains may contain a cerium compound, may contain at least one selected from the group consisting of cerium oxide and cerium hydroxide, and may contain cerium oxide.

A content of the cerium compound in the abrasive grains (when the abrasive grains contain at least one of cerium oxide and cerium hydroxide, the total content of cerium oxide and cerium hydroxide) may be more than 95 mass %, 98 mass % or more, 99 mass % or more, 99.5 mass % or more, or 99.9 mass % or more, based on the entire abrasive grains (the entire abrasive grains contained in the polishing liquid or the entire one particle constituting the abrasive grains) from the viewpoint of easily stabilizing the polishing rate for silicon oxide. The abrasive grains may be substantially composed of a cerium compound (in which substantially 100 mass % of the abrasive grains is a cerium compound). From the same viewpoint, a content of cerium oxide in the abrasive grains may be in the same numerical range as the numerical range of the content of the cerium compound in the abrasive grains.

The abrasive grains may be colloidal, and may contain, for example, colloidal ceria. A polishing liquid containing colloidal abrasive grains is a suspension of abrasive grains, and has a state in which cerium oxide forming the abrasive grains is dispersed in water. The colloidal abrasive grains can be obtained, for example, by a liquid phase method, and are abrasive grains derived from a liquid phase method. Examples of the liquid phase method include a colloid method, a hydrothermal synthesis method, a sol-gel method, a neutralization decomposition method, a hydrolysis method, a chemical precipitation method, a coprecipitation method, an atomizing method, a reverse-micelle method, and an emulsion method. The abrasive grains may have crystal grain boundaries and may not have crystal grain boundaries.

As the colloidal abrasive grains, abrasive grains having τ2 of 0.3650 ns or less in positron lifetimes τ1 to τ4 can be used. Here, the “positron lifetime” is a time until a positron released from ²²Na is annihilated with an electron, and can be used as a probe of ultrafine voids such as sub-nanometer to nanometer order lattice defects and free volumes. That is, the shorter the positron lifetime, the higher the denseness of the particles.

For the measurement of the positron lifetime, PAS Type L-II manufactured by TOYO SEIKO CO., LTD. can be used. A powder obtained by vacuum-drying abrasive grains at room temperature (25° C.) for 24 hours is placed in a powder measurement box, the powder measurement box is then set in a positron beam source portion, and measurement is performed until the cumulative number reaches 1,000,000 counts. The life histogram is separated into two components and analyzed using IPALM that is software attached to the apparatus. Since some of the positrons released from ²²Na are annihilated by a positron radiation source itself such as Kapton or an adhesive, and the components thereof are mixed in the measurement result, analysis is performed assuming that a proportion of Kapton is 30%. Among the obtained positron lifetimes τ1 to τ4, τ1 and τ2 correspond to a positron lifetime derived from the sample, τ3 corresponds to a positron lifetime derived from Kapton, and τ4 corresponds to a positron lifetime derived from the adhesive. In addition, τ1 corresponds to a small void like a single pore, and τ2 corresponds to a void in which a plurality of voids are clustered.

As the colloidal abrasive grains, abrasive grains in which a regular diffraction spot is observed in electron beam diffraction of a transmission electron microscope (TEM) can be used. For example, when colloidal ceria is used as the abrasive grains, in a diffraction spot obtained when an electron beam is applied vertically to a (111) plane of ceria, in a case where two diffraction spots A1 and A2 adjacent to each other and a diffraction spot B adjacent to the diffraction spots A1 and A2 are observed, abrasive grains, which have the diffraction spot B having a distance R between the diffraction spots (a distance between the diffraction spot A1 and the diffraction spot B and a distance between the diffraction spot A2 and the diffraction spot B) of 1.6 to 2.2 Å and having a minimum value of an angle α formed by the diffraction spots A1 and A2 using the diffraction spot B as a center of 58 to 62°, may account for 50% or more.

For the observation of the abrasive grains and the measurement of the distance R between the diffraction spots and the angle α, JEM-2100F manufactured by JEOL Ltd. can be used. In a TEM grid attached with the abrasive grains, one particle of the abrasive grains is subjected to electron beam diffraction under the conditions of an acceleration voltage of 200 kV, an electron beam wavelength of 2.508 pm, and a camera length of 30 cm, such that the distance R and the angle α can be measured. The distance R and the angle α are measured at at least three points with respect to one abrasive grain, and an average value thereof can be adopted. The measurement is performed for all 100 or more abrasive grains confirmed in one field of view under an arbitrary magnification in TEM observation, and a proportion of the abrasive grains satisfying the above-described conditions can be calculated.

An average particle diameter of the abrasive grains may be in the following range. The average particle diameter of the abrasive grains can be adjusted by spontaneous precipitation, a pulverization treatment, dispersion, filtration, or the like, and for example, the particle diameter may be adjusted before or after mixing the constituent components of the polishing liquid.

An average particle diameter D50 of the abrasive grains may be 1 nm or more, 3 nm or more, 5 nm or more, 10 nm or more, 30 nm or more, 50 nm or more, 80 nm or more, 100 nm or more, more than 100 nm, 120 nm or more, 130 nm or more, or 140 nm or more, from the viewpoint of easily stabilizing the polishing rate for silicon oxide. The average particle diameter D50 of the abrasive grains may be 500 nm or less, 300 nm or less, 200 nm or less, 180 nm or less, 160 nm or less, 155 nm or less, 150 nm or less, or 145 nm or less, from the viewpoint of easily stabilizing the polishing rate for silicon oxide. From these viewpoints, the average particle diameter D50 of the abrasive grains may be 1 to 500 nm. The average particle diameter D50 of the abrasive grains means a 50% particle diameter of a volume-based cumulative distribution, and can be measured by, for example, a laser diffraction particle diameter distribution meter.

A content of the abrasive grains may be in the following range based on the total mass of the polishing liquid from the viewpoint of easily stabilizing the polishing rate for silicon oxide. The content of the abrasive grains may be 0.01 mass % or more, 0.03 mass % or more, 0.05 mass % or more, 0.08 mass % or more, 0.10 mass % or more, 0.20 mass % or more, or 0.25 mass % or more. The content of the abrasive grains may be 10 mass % or less, 5.0 mass % or less, 3.0 mass % or less, 1.0 mass % or less, less than 1.0 mass %, 0.80 mass % or less, 0.50 mass % or less, less than 0.50 mass %, 0.40 mass % or less, 0.30 mass % or less, or 0.25 mass % or less. From these viewpoints, the content of the abrasive grains may be 0.01 to 10 mass %.

### (Ether Compound)

The polishing liquid according to the present embodiment contains an ether compound (hereinafter, referred to as “ether compound A”) having at least one selected from the group consisting of a carboxy group and a carboxylate group from the viewpoint of reducing the polishing rate for silicon oxide. The ether compound A is a compound having one or more ether groups and one or more carboxy groups or carboxylate groups. Examples of the carboxylate group include a functional group in which a hydrogen atom of a carboxy group is substituted with a metal atom (a sodium atom, a potassium atom, or the like).

When the polishing liquid contains the ether compound A, the polishing rate for silicon oxide can be reduced. The reason for this is not clear, but it is presumed that the oxygen atom of the ether group of the ether compound A and the oxygen atom of the carboxy group or the carboxylate group adhere to the surfaces of the abrasive grains in a bidentate manner, thereby suppressing the polishing of silicon oxide. However, the present disclosure is not limited to the above reason. In addition, the polishing liquid contains the ether compound A, such that the polishing rate for silicon nitride can be reduced. The same reason as the above reason for reducing the polishing rate for silicon oxide is presumed as the reason, and the present disclosure is not limited to the above reason.

The number of carbon atoms in the ether compound A may be 3 or more from the viewpoint of easily reducing the polishing rate for silicon oxide. The number of carbon atoms in the ether compound A may be 50 or less, 40 or less, 30 or less, 20 or less, 10 or less, 8 or less, 6 or less, 5 or less, or 4 or less, from the viewpoint of easily reducing the polishing rate for silicon oxide. From these viewpoints, the number of carbon atoms in the ether compound A may be 3 to 50, 3 to 30, 3 to 10, or 3 to 6. The number of carbon atoms in the ether compound A may be 4 or more. The number of carbon atoms in the ether compound A may be 3 or less.

A molecular weight of the ether compound A may be in the following range from the viewpoint of easily reducing the polishing rate for silicon oxide. The molecular weight of the ether compound A may be 50 or more, 55 or more, 60 or more, 65 or more, 70 or more, 75 or more, 80 or more, 85 or more, or 90 or more. The molecular weight of the ether compound A may be 500 or less, 400 or less, 300 or less, 250 or less, 200 or less, 150 or less, 130 or less, 120 or less, 115 or less, 110 or less, or 105 or less. From these viewpoints, the molecular weight of the ether compound A may be 50 to 500. The molecular weight of the ether compound A may be 95 or more or 100 or more. The molecular weight of the ether compound A may be 100 or less or 95 or less.

The number of ether groups in the ether compound A may be in the following range from the viewpoint of easily reducing the polishing rate for silicon oxide. The number of ether groups may be 10 or less, 8 or less, 5 or less, 4 or less, 3 or less, 2 or less, or 1. The number of ether groups may be 1 or more. From these viewpoints, the number of ether groups may be 1 to 10.

The total number of carboxy groups and carboxylate groups in the ether compound A may be in the following range from the viewpoint of easily reducing the polishing rate for silicon oxide. The total number of carboxy groups and carboxylate groups may be 10 or less, 8 or less, 5 or less, 4 or less, 3 or less, 2 or less, or 1. The total number of carboxy groups and carboxylate groups may be 1 or more. From these viewpoints, the total number of carboxy groups and carboxylate groups may be 1 to 10.

The ether compound A may have a functional group other than an ether group, a carboxy group, and a carboxylate group, and may not have a functional group other than an ether group, a carboxy group, and a carboxylate group, from the viewpoint of easily reducing the polishing rate for silicon oxide. Examples of the functional group other than the ether group, the carboxy group, and the carboxylate group include a hydroxy group, an epoxy group, a phosphono group, a phosphonate group, an amino group, a cyano group, a sulfo group, and a sulfonate group. The total number of functional groups other than the ether group, the carboxy group, and the carboxylate group in the ether compound A may be 10 or less, 8 or less, 6 or less, 4 or less, 3 or less, 2 or less, or 1 or less, from the viewpoint of easily reducing the polishing rate for silicon oxide.

The ether compound A may have at least one selected from the group consisting of an aromatic ring and a heteroaromatic ring, and may not have an aromatic ring and a heteroaromatic ring from the viewpoint of easily reducing the polishing rate for silicon oxide. The total number of aromatic rings and heteroaromatic rings in the ether compound A may be 5 or less, 4 or less, 3 or less, 2 or less, or 1 or less, from the viewpoint of easily reducing the polishing rate for silicon oxide.

The ether compound A may have an unsaturated carbon-carbon bond, and may not have an unsaturated carbon-carbon bond from the viewpoint of easily reducing the polishing rate for silicon oxide. The number of unsaturated carbon-carbon bonds in the ether compound A may be 5 or less, 4 or less, 3 or less, 2 or less, or 1 or less, from the viewpoint of easily reducing the polishing rate for silicon oxide.

The ether compound A may include a chain ether compound (ether compound having no cyclic structure) from the viewpoint of easily reducing the polishing rate for silicon oxide. The ether compound A may include a compound represented by the following General Formula (1) from the viewpoint of easily reducing the polishing rate for silicon oxide.

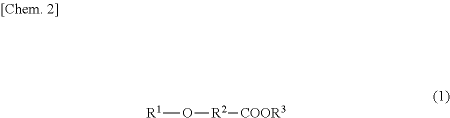

[In Formula (1), R¹ represents an alkyl group having 1 to 10 carbon atoms, R² represents an alkylene group having 1 to 10 carbon atoms, and R³ represents a hydrogen atom or a monovalent metal atom.]

The number of carbon atoms in the alkyl group of R¹ may be 8 or less, 6 or less, 5 or less, 4 or less, 3 or less, or 2 or less, from the viewpoint of easily reducing the polishing rate for silicon oxide. The number of carbon atoms in the alkyl group of R¹ may be 1 to 5 from the viewpoint of easily reducing the polishing rate for silicon oxide. The number of carbon atoms in the alkyl group of R¹ may be 2 or more. R¹ may be an alkyl group having no substituent.

The number of carbon atoms in the alkylene group of R² may be 8 or less, 6 or less, 5 or less, 4 or less, 3 or less, 2 or less, or 1, from the viewpoint of easily reducing the polishing rate for silicon oxide. The number of carbon atoms in the alkylene group of R² may be 1 to 5 from the viewpoint of easily reducing the polishing rate for silicon oxide. R² may be an alkylene group having no substituent.

Examples of the ether compound A include methoxyacetic acid, ethoxyacetic acid, propoxyacetic acid, butoxyacetic acid, 3-methoxypropionic acid, 2-methoxybutanoic acid, and salts thereof. The ether compound A may include an ether compound having an —O—CH₂—COOR (R represents a hydrogen atom or a monovalent metal atom) structure and may include at least one selected from the group consisting of methoxyacetic acid, ethoxyacetic acid, and salts thereof, from the viewpoint of easily reducing the polishing rate for silicon oxide. The ether compound A may not include 2-furancarboxylic acid, 2,5-furandicarboxylic acid, diglycolic acid, and salts thereof.

A content of the ether compound A may be in the following range based on the total mass of the polishing liquid. The content of the ether compound A may be 0.0010 mass % or more, 0.0030 mass % or more, 0.0050 mass % or more, 0.0070 mass % or more, 0.010 mass % or more, 0.015 mass % or more, 0.020 mass % or more, or 0.025 mass % or more, from the viewpoint of easily reducing the polishing rate for silicon oxide. The content of the ether compound A may be 10 mass % or less, 5.0 mass % or less, 1.0 mass % or less, less than 1.0 mass %, 0.70 mass % or less, 0.50 mass % or less, less than 0.50 mass %, 0.40 mass % or less, less than 0.40 mass %, 0.30 mass % or less, 0.20 mass % or less, 0.10 mass % or less, less than 0.10 mass %, 0.070 mass % or less, 0.050 mass % or less, less than 0.050 mass %, 0.030 mass % or less, or 0.025 mass % or less, from the viewpoint of easily stabilizing the polishing rate for silicon oxide. From these viewpoints, the content of the ether compound A may be 0.0010 to 10 mass %.

The content of the ether compound A may be in the following range with respect to 100 parts by mass of the abrasive grains. The content of the ether compound A may be 0.1 parts by mass or more, 0.5 parts by mass or more, 1 part by mass or more, more than 1 part by mass, 3 parts by mass or more, 5 parts by mass or more, 7 parts by mass or more, or 10 parts by mass or more, from the viewpoint of easily reducing the polishing rate for silicon oxide. The content of the ether compound A may be 200 parts by mass or less, 150 parts by mass or less, 100 parts by mass or less, 70 parts by mass or less, 50 parts by mass or less, 40 parts by mass or less, less than 40 parts by mass, 30 parts by mass or less, 20 parts by mass or less, or 10 parts by mass or less, from the viewpoint of easily stabilizing the polishing rate for silicon oxide. From these viewpoints, the content of the ether compound A may be 0.1 to 200 parts by mass.

### (Additives)

The polishing liquid according to the present embodiment may contain a component other than the abrasive grains, the ether compound A, and water. Examples of such a component include an ether compound other than the ether compound A (hereinafter, referred to as “ether compound B”), a nitrogen-containing compound, an acid component, an oxidizing agent, a quaternary ammonium salt, a surfactant, and a chelating agent. The polishing liquid according to the present embodiment may not contain at least one of these components.

The polishing liquid according to the present embodiment may contain an ether compound B. Examples of the ether compound B include a polyether compound. Examples of the polyether compound include polyglycerin, polysaccharides (for example, dextrin), polyalkylene glycol, polyoxypropylene polyglyceryl ether, polyoxyethylene polyglyceryl ether, 1,4-di(2-hydroxyethoxy)benzene, 2,2-bis(4-polyoxyethyleneoxyphenyl)propane, 2,2-bis(4-polyoxypropyleneoxyphenyl)propane, ethylene glycol monophenyl ether, diethylene glycol monophenyl ether, polyoxyalkylene monophenyl ether, propylene glycol monophenyl ether, polyoxypropylene monomethylphenyl ether, polyethylene glycol monomethyl ether, pentaerythritol polyoxyethylene ether, ethylene glycol monoallyl ether, polyoxyethylene monoallyl ether, and alkyl glucoside.

A content of the ether compound B may be in the following range based on the total mass of the polishing liquid of the polishing liquid. The content of the ether compound B may be 0.001 mass % or more, 0.005 mass % or more, 0.01 mass % or more, 0.05 mass % or more, 0.08 mass % or more, 0.1 mass % or more, 0.2 mass % or more, 0.3 mass % or more, or 0.35 mass % or more, from the viewpoint of easily stabilizing the polishing rate for silicon oxide. The content of the ether compound B may be 5 mass % or less, 4 mass % or less, 3 mass % or less, 2 mass % or less, 1 mass % or less, 0.8 mass % or less, 0.6 mass % or less, 0.5 mass % or less, or 0.4 mass % or less, from the viewpoint of easily stabilizing the polishing rate for silicon oxide. From these viewpoints, the content of the ether compound B may be 0.001 to 5 mass %.

The polishing liquid according to the present embodiment may contain a nitrogen-containing compound (however, compounds corresponding to the ether compound A, the ether compound B, the oxidizing agent, the quaternary ammonium salt, the surfactant, and the chelating agent are excluded). The nitrogen-containing compound means a compound containing one or more nitrogen atoms in the molecule. Examples of the nitrogen-containing compound include an amino acid, a pyridine compound, a pyrazole compound, a triazole compound, a pyrimidine compound, and an imidazole compound.

Examples of the amino acid include alanine (α-alanine or β-alanine), arginine, asparagine, aspartic acid, cysteine, glutamine, glutamic acid, glycine, histidine, isoleucine, leucine, lysine, methionine, phenylalanine, proline, serine, threonine, tryptophan, tyrosine, and valine.

Examples of the pyridine compound include pyridine, methylpyridine, acetylpyridine, pyridinamide (nicotinamide), and aminopyridine.

Examples of the pyrazole compound include pyrazole, N-methylpyrazole, 3,5-dimethylpyrazole, 1-allyl-3,5-dimethylpyrazole, 3,5-di(2-pyridyl)pyrazole, 3,5-diisopropylpyrazole, 3,5-dimethyl-1-hydroxymethyl pyrazole, 3,5-dimethyl-1-phenylpyrazole, and 4-methylpyrazole.

Examples of the pyrimidine compound include pyrimidine, 1,3-diphenyl-pyrimidine-2,4,6-trione, 1,4,5,6-tetrahydropyrimidine, 2,4,5-trihydroxypyrimidine, 2,4,6-trichloropyrimidine, 2,4,6-trimethoxypyrimidine, and 2,4,6-triphenylpyrimidine.

Examples of the imidazole compound include imidazole, 1,1′-carbonylbis-1H-imidazole, 1,1′-oxalyldiimidazole, 1,2,4,5-tetramethylimidazole, 1,2-dimethyl-5-nitroimidazole, 1,2-dimethylimidazole, 1-butylimidazole, 1-ethylimidazole, 1-methylimidazole, and benzimidazole.

The nitrogen-containing compound may include at least one selected from the group consisting of an amino acid, a pyridine compound, and a pyrazole compound, and may include at least one selected from the group consisting of β-alanine, pyridinamide, and 3,5-dimethylpyrazole, from the viewpoint of easily stabilizing the polishing rate for silicon oxide.

A content of the nitrogen-containing compound may be in the following range based on the total mass of the polishing liquid. The content of the nitrogen-containing compound may be 0.0001 mass % or more, 0.0005 mass % or more, 0.001 mass % or more, 0.003 mass % or more, or 0.005 mass % or more, from the viewpoint of easily stabilizing the polishing rate for silicon oxide. The content of the nitrogen-containing compound may be 1 mass % or less, 0.5 mass % or less, 0.1 mass % or less, 0.08 mass % or less, 0.05 mass % or less, 0.03 mass % or less, 0.01 mass % or less, 0.008 mass % or less, or 0.006 mass % or less, from the viewpoint of easily stabilizing the polishing rate for silicon oxide. From these viewpoints, the content of the nitrogen-containing compound may be 0.0001 to 1 mass %.

The polishing liquid according to the present embodiment may contain an acid component. The polishing liquid according to the present embodiment may contain an organic acid component or an inorganic acid component as an acid component.

Examples of the organic acid component include an organic acid (excluding an amino acid), an organic acid ester, an organic acid salt, and an amino acid. Examples of the organic acid include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, 3-methylphthalic acid, 4-methylphthalic acid, 3-aminophthalic acid, 4-aminophthalic acid, 3-nitrophthalic acid, 4-nitrophthalic acid, glutaric acid, adipic acid, pimelic acid, maleic acid, phthalic acid, isophthalic acid, malic acid, tartaric acid, citric acid, p-toluenesulfonic acid, p-phenolsulfonic acid, methylsulfonic acid, lactic acid, itaconic acid, maleic acid, quinaldic acid, adipic acid, and pimelic acid. Examples of the organic acid ester include esters of the organic acids described above. Examples of the organic acid salt include ammonium salts, alkali metal salts, alkaline earth metal salts, and halides of the organic acids described above.

Examples of the inorganic acid component include an inorganic acid, an ammonium salt of an inorganic acid, and chromic acid. Examples of the inorganic acid include hydrochloric acid, sulfuric acid, and nitric acid. Examples of the ammonium salt of the inorganic acid include ammonium salts of monovalent inorganic acids such as ammonium nitrate, ammonium chloride, and ammonium bromide; ammonium salts of divalent inorganic acids such as ammonium carbonate, ammonium sulfate, and ammonium persulfate; and ammonium salts of trivalent inorganic acids such as ammonium phosphate and ammonium borate.

A content of the acid component may be in the following range based on the total mass of the polishing liquid. The content of the acid component may be 0.001 mass % or more, 0.005 mass % or more, 0.01 mass % or more, 0.03 mass % or more, 0.05 mass % or more, 0.06 mass % or more, 0.07 mass % or more, 0.08 mass % or more, 0.09 mass % or more, 0.1 mass % or more, or 0.11 mass % or more, from the viewpoint of easily stabilizing the polishing rate for silicon oxide. The content of the acid component may be 5 mass % or less, 4 mass % or less, 3 mass % or less, 2 mass % or less, 1 mass % or less, 0.8 mass % or less, 0.5 mass % or less, 0.4 mass % or less, 0.3 mass % or less, 0.2 mass % or less, or 0.15 mass % or less, from the viewpoint of easily stabilizing the polishing rate for silicon oxide. From these viewpoints, the content of the acid component may be 0.001 to 5 mass %.

The polishing liquid according to the present embodiment may contain an oxidizing agent or may not contain an oxidizing agent (a content of the oxidizing agent may be substantially 0 mass % based on the total mass of the polishing liquid). Examples of the oxidizing agent include hydrogen peroxide, peroxide, nitrate, iodate, periodate, hypochlorite, chlorite, chlorate, perchlorate, persulfate, dichromate, permanganate, ozone water, silver(II) salt, and iron(III) salt. A content of the oxidizing agent may be less than 0.01 mol based on 1 L of the polishing liquid.

The polishing liquid according to the present embodiment may contain a quaternary ammonium salt or may not contain a quaternary ammonium salt (a content of the quaternary ammonium salt may be substantially 0 mass % based on the total mass of the polishing liquid). Examples of the quaternary ammonium salt include a tetramethylammonium salt, a tetraethylammonium salt, a tetrapropylammonium salt, a tetrabutylammonium salt, and a tetrapentylammonium salt. A content of the quaternary ammonium salt may be less than 0.00001 mass % based on the total mass of the polishing liquid.

The polishing liquid according to the present embodiment may contain a surfactant or may not contain a surfactant (a content of the surfactant may be substantially 0 mass % based on the total mass of the polishing liquid). Examples of the surfactant include decyl benzene sulfonic acid, dodecyl benzene sulfonic acid, tetradecyl benzene sulfonic acid, hexadecyl benzene sulfonic acid, dodecyl naphthalene sulfonic acid, and tetradecyl naphthalene sulfonic acid. A content of the surfactant may be less than 0.001 g based on 1 L of the polishing liquid.

The polishing liquid according to the present embodiment may contain a chelating agent or may not contain a chelating agent (a content of the chelating agent may be substantially 0 mass % based on the total mass of the polishing liquid). Examples of the chelating agent include nitrilotriacetic acid, diethylenetriaminepentaacetic acid, ethylenediaminetetraacetic acid, N,N,N-trimethylenephosphonic acid, ethylenediamine-N,N,N′,N′-tetramethylenesulfonic acid, trans-cyclohexanediaminetetraacetic acid, 1,2-diaminopropanetetraacetic acid, ethylenediamine orthohydroxyphenylacetic acid, ethylenediamine succinic acid (SS form), N-(2-carboxylethyl)-L-aspartic acid, β-alanine diacetic acid, 2-phosphonobutane-1,2,4-tricarboxylic acid, 1-hydroxyethylidene-1,1-diphosphonic acid, N,N′-bis(2-hydroxybenzyl)ethylenediamine-N,N′-diacetic acid, and 1,2-dihydroxybenzene-4,6-disulfonic acid. A content of the chelating agent may be less than 0.0003 mol based on 1 L of the polishing liquid.

### (Water)

The polishing liquid according to the present embodiment contains water. Water may be contained as a remainder obtained by removing other constituent components from the polishing liquid. A content of water may be in the following range based on the total mass of the polishing liquid. The content of water may be 90.0 mass % or more, 93.0 mass % or more, 95.0 mass % or more, 97.0 mass % or more, 99.0 mass % or more, 99.2 mass % or more, 99.4 mass % or more, 99.5 mass % or more, 99.6 mass % or more, or 99.7 mass % or more. The content of water may be less than 100 mass %, 99.9 mass % or less, 99.8 mass % or less, or 99.7 mass % or less. From these viewpoints, the content of water may be 90.0 mass % or more and less than 100 mass %.

A pH of the polishing liquid according to the present embodiment may be in the following range from the viewpoint of easily reducing the polishing rate for silicon oxide. The pH of the polishing liquid may be 2.0 or more, 2.5 or more, more than 2.5, 2.6 or more, 2.7 or more, 2.8 or more, 2.9 or more, 3.0 or more, more than 3.0, or 3.1 or more. The pH of the polishing liquid may be 5.0 or less, less than 5.0, 4.5 or less, 4.0 or less, less than 4.0, 3.8 or less, 3.6 or less, 3.5 or less, less than 3.5, 3.4 or less, or 3.3 or less. From these viewpoints, the pH of the polishing liquid may be 2.0 to 5.0. The pH of the polishing liquid may be 2.0 or more, 2.5 or more, 3.0 or more, 3.1 or more, 3.2 or more, 3.3 or more, 3.4 or more, 3.5 or more, 3.6 or more, 3.7 or more, 3.8 or more, 3.9 or more, or 4.0 or more, and may be 5.0 or less, 4.9 or less, 4.8 or less, 4.7 or less, 4.6 or less, 4.5 or less, 4.4 or less, 4.3 or less, 4.2 or less, 4.1 or less, or 4.0 or less, from the viewpoint of improving the polishing rate ratio of silicon oxide to silicon nitride.

The pH of the polishing liquid according to the present embodiment can be measured with a pH meter (for example, model number: PHL-40, manufactured by DKK-TOA CORPORATION). For example, the pH meter is subjected to two-point calibration using a phthalate pH buffer solution (pH: 4.01) and a neutral phosphate pH buffer solution (pH: 6.86) as standard buffer solutions, an electrode of the pH meter is placed in the polishing liquid, and then, a value after stabilization for 2 minutes or longer is measured. At this time, the liquid temperatures of the standard buffer solutions and the polishing liquid are set to 25° C.

### (Others)

The polishing liquid according to the present embodiment may be stored as a one-pack polishing liquid containing at least abrasive grains, an ether compound A, and water. The one-pack polishing liquid may be stored as a storage liquid for a polishing liquid in which a content of water is reduced, and may be diluted with water immediately before polishing or during polishing and then used.

In the case of the one-pack polishing liquid, as a method of supplying a polishing liquid onto a polishing platen, a method of directly feeding and supplying a polishing liquid; a method in which a storage liquid for a polishing liquid and water are fed by separate pipes, and the polishing liquid and water are merged and mixed and then supplied; and a method of mixing and supplying a storage liquid for a polishing liquid and water in advance can be used.

### <Polishing Liquid Set>

In the polishing liquid according to the present embodiment, as a multiple-liquid type (for example, two-liquid type) polishing liquid set (for example, a polishing liquid set for CMP), constituent components of a polishing liquid may be stored separately in a first liquid and a second liquid so that the first liquid (slurry) and the second liquid (additive liquid) are mixed to obtain the polishing liquid described above. The first liquid contains, for example, at least abrasive grains and water. The second liquid contains, for example, at least an ether compound A and water. The constituent components of the polishing liquid may be stored as a polishing liquid set divided into three or more liquids.

In the polishing liquid set, the first liquid and the second liquid are mixed immediately before polishing or during polishing to prepare a polishing liquid. The multiple-liquid type polishing liquid set may be stored as a storage liquid for a slurry and a storage liquid for an additive liquid in which a content of water is reduced, and may be used by being diluted with water immediately before polishing or during polishing.

When the polishing liquid is stored as a multiple-liquid type polishing liquid set containing a first liquid and a second liquid, the polishing rate can be adjusted by arbitrarily changing the formulation of each liquid. In the case of polishing using a polishing liquid set, as a method of supplying a polishing liquid onto a polishing platen, there is the following method. For example, a method in which a first liquid and a second liquid are fed by separate pipes, and these pipes are merged to mix and supply the first liquid and the second liquid; a method in which a storage liquid for a slurry, a storage liquid for an additive liquid, and water are fed by separate pipes, and these liquids and water are merged and mixed and then supplied; a method of mixing and supplying a first liquid and a second liquid in advance; and a method of mixing and supplying a storage liquid for a slurry, a storage liquid for an additive liquid, and water in advance can be used. In addition, it is also possible to use a method of supplying each of a first liquid and a second liquid in a polishing liquid set onto a polishing platen. In this case, a surface to be polished is polished using the polishing liquid obtained by mixing the first liquid and the second liquid on the polishing platen.

### <Polishing Method>

A polishing method according to the present embodiment may include a polishing step of polishing a surface to be polished using a one-pack polishing liquid, or may include a polishing step of polishing a surface to be polished using a polishing liquid obtained by mixing a first liquid and a second liquid in a polishing liquid set. The polishing method according to the present embodiment is, for example, a polishing method of a substrate having a surface to be polished.

In the polishing method according to the present embodiment, the surface to be polished is polished using the polishing liquid according to the present embodiment. The surface to be polished may contain silicon oxide and may contain silicon oxide derived from TEOS. A material to be polished having the surface to be polished may be a single material or a plurality of materials. The material to be polished may be in the form of a film (film to be polished), a silicon oxide film, or a TEOS film.

The polishing method according to the present embodiment may be a polishing method of a substrate having a surface to be polished containing silicon nitride. The polishing method according to the present embodiment may be a polishing method of a substrate having a surface to be polished containing silicon oxide and silicon nitride.

In the polishing step, for example, in a state where the surface to be polished of the substrate having the surface to be polished is pressed against a polishing pad (polishing cloth) of a polishing platen, a polishing liquid is supplied between the surface to be polished and the polishing pad, and the surface to be polished is polished by relatively moving the substrate and the polishing platen. In the polishing step, for example, at least a part of the material to be polished is removed by polishing.

Examples of the substrate to be polished include a substrate in which a material to be polished is formed on a substrate (for example, a semiconductor substrate on which an STI pattern, a gate pattern, a wiring pattern, or the like is formed) related to semiconductor element manufacturing. Examples of the material to be polished include an insulating material such as silicon oxide; and a stopper material such as silicon nitride or polysilicon. The material to be polished may be a single material or a plurality of materials. When a plurality of materials are exposed on the surface to be polished, the plurality of materials can be regarded as materials to be polished. The material to be polished may be in the form of a film (film to be polished). The shape of the insulating member is not particularly limited, and is, for example, in the form of a film (insulating film). The shape of the stopper is not particularly limited, and is, for example, in the form of a film (stopper film: silicon nitride film, polysilicon film, or the like).

By polishing the material to be polished (for example, an insulating film such as a silicon oxide film) formed on the substrate using the polishing liquid according to the present embodiment to remove an excess portion, irregularities on the surface of the material to be polished are eliminated, and a smooth surface can be obtained over the entire surface to be polished.

In the present embodiment, it is possible to polish the insulating member in a substrate that has a substrate having a concave-convex pattern, a stopper disposed on the convex portion of the substrate, and an insulating member disposed on the substrate and the stopper so as to fill the concave portion of the concave-convex pattern (a substrate that has an insulating member (for example, a silicon oxide film containing silicon oxide formed on at least a surface), a stopper disposed on a lower layer of the insulating member, and a semiconductor substrate disposed below the stopper). The stopper material constituting the stopper is, for example, a material having a polishing rate lower than that of the insulating material, and examples thereof include silicon nitride and polysilicon.

In the polishing method according to the present embodiment, a general polishing apparatus including a holder capable of holding a substrate (semiconductor substrate or the like) having a surface to be polished and a polishing platen to which a polishing pad can be attached can be used as the polishing apparatus. A motor or the like capable of changing a rotational speed is attached to each of the holder and the polishing platen. As the polishing apparatus, for example, a polishing apparatus: Mirra3400 manufactured by APPLIED MATERIALS Inc. can be used.

As the polishing pad, a general non-woven fabric, foam, non-foam, or the like can be used. As a material of the polishing pad, a resin such as polyurethane, an acrylic resin, polyester, an acrylic-ester copolymer, polytetrafluoroethylene, polypropylene, polyethylene, poly 4-methylpentene, cellulose, a cellulose ester, polyamide (for example, Nylon (trade name) and aramid), polyimide, polyimide-amide, a polysiloxane copolymer, an oxirane compound, a phenolic resin, polystyrene, polycarbonate, or an epoxy resin can be used. The material of the polishing pad may be foamed polyurethane or non-foamed polyurethane from the viewpoint of further excellent flatness. The polishing pad may be subjected to grooving so that the polishing liquid accumulates.

The polishing conditions are not limited, and a rotational speed of the polishing platen may be 200 rpm (=rotations/min) or less so that the substrate does not jump out, and a polishing pressure (processing load) applied to the substrate may be 100 kPa or less, from the viewpoint of sufficiently suppressing the occurrence of polishing scratches. During the polishing, the polishing liquid may be continuously supplied to the polishing pad with a pump or the like. The amount of the polishing liquid supplied is not limited, and a surface of the polishing pad may be always covered with the polishing liquid.

It is preferable that the substrate after completion of polishing be thoroughly washed in flowing water to remove particles adhering to the substrate. For the washing, dilute hydrofluoric acid or ammonia water may be used in addition to pure water, and a brush may be used to increase the washing efficiency. In addition, it is preferable that, after the washing, water droplets adhering to the substrate are removed using a spin dryer or the like and then the substrate is dried.

A method for manufacturing a component according to the present embodiment includes a component preparation step of obtaining a component using a substrate (body to be polished) polished by the polishing method according to the present embodiment. The component according to the present embodiment is a component obtained by the method for manufacturing a component according to the present embodiment. The component according to the present embodiment is not particularly limited, and may be an electronic component (for example, a semiconductor component such as a semiconductor package), a wafer (for example, a semiconductor wafer), or a chip (for example, a semiconductor chip). As an aspect of the method for manufacturing a component according to the present embodiment, in a method for manufacturing an electronic component according to the present embodiment, an electronic component is obtained using a substrate polished by the polishing method according to the present embodiment. As an aspect of the method for manufacturing a component according to the present embodiment, in a method for manufacturing a semiconductor component according to the present embodiment, a semiconductor component (for example, a semiconductor package) is obtained using a substrate polished by the polishing method according to the present embodiment. The method for manufacturing a component according to the present embodiment may include, before the component preparation step, a polishing step of polishing a substrate by the polishing method according to the present embodiment.

The method for manufacturing a component according to the present embodiment may include, as an aspect of the component preparation step, a segmentation step of segmenting a substrate (body to be polished) polished by the polishing method according to the present embodiment. The segmentation step may be, for example, a step of dicing a wafer (for example, a semiconductor wafer) polished by the polishing method according to the present embodiment to obtain a chip (for example, a semiconductor chip). As an aspect of the method for manufacturing a component according to the present embodiment, the method for manufacturing an electronic component according to the present embodiment may include a step of obtaining an electronic component (for example, a semiconductor component) by segmenting a substrate polished by the polishing method according to the present embodiment. As an aspect of the method for manufacturing a component according to the present embodiment, the method for manufacturing a semiconductor component according to the present embodiment may include a step of obtaining a semiconductor component (for example, a semiconductor package) by segmenting a substrate polished by the polishing method according to the present embodiment.

The method for manufacturing a component according to the present embodiment may include, as an aspect of the component preparation step, a connection step of connecting (for example, electrically connecting) a substrate (body to be polished) polished by the polishing method according to the present embodiment and another body to be connected. The body to be connected to the substrate polished by the polishing method according to the present embodiment is not particularly limited, and may be a substrate polished by the polishing method according to the present embodiment, or may be a body to be connected different from the substrate polished by the polishing method according to the present embodiment. In the connection step, the substrate and the body to be connected may be directly connected (connected in a state where the substrate and the body to be connected are in contact with each other), or the substrate and the body to be connected may be connected via another member (a conductive member or the like). The connection step can be performed before the segmentation step, after the segmentation step, or before and after the segmentation step.

The connection step may be a step of connecting a surface to be polished of a substrate polished by the polishing method according to the present embodiment and a body to be connected, or may be a step of connecting a connection surface of a substrate polished by the polishing method according to the present embodiment and a connection surface of a body to be connected. The connection surface of the substrate may be a surface to be polished by the polishing method according to the present embodiment. By the connection step, a connection body including a substrate and a body to be connected can be obtained. In the connection step, when the connection surface of the substrate has a metal portion, the body to be connected may be brought into contact with the metal portion. In the connection step, when a connection surface of the substrate has a metal portion and a connection surface of a body to be connected has a metal portion, the metal portions may be brought into contact with each other. The metal portion may contain copper.

A device (for example, an electronic device such as a semiconductor device) according to the present embodiment includes at least one selected from the group consisting of a substrate polished by the polishing method according to the present embodiment and a component according to the present embodiment.

### EXAMPLES

Hereinafter, the present disclosure will be specifically described based on Examples, but the present disclosure is not limited thereto.

### <Preparation of Polishing Liquid>

### Examples 1 to 4 and Comparative Examples 1 to 8

Water was added to a liquid containing colloidal ceria particles (trade name: Zenus (registered trademark) HC60, manufactured by Solvay, content of particles: 30 mass %), and then, a particle diameter was adjusted, thereby obtaining a slurry containing 5.0 mass % of colloidal ceria particles (abrasive grains).

Water and each of the additives shown in Table 1 were added to the slurry to obtain a polishing liquid containing 0.25 mass % of colloidal ceria particles (abrasive grains) and 0.025 mass % of an additive. In Examples 4 and 5, ammonia water was added in order to adjust the pH.

<Measurement of pH>

The pH of each of the polishing liquids of Examples 1 and 2 was measured using a pH meter (model number: PHL-40, manufactured by DKK-TOA CORPORATION). The pH meter was subjected to two-point calibration using a phthalate pH buffer solution (pH: 4.01) and a neutral phosphate pH buffer solution (pH: 6.86) as standard buffer solutions, an electrode of the pH meter was placed in the polishing liquid, and then, a value after stabilization for 2 minutes or longer was measured. The pH of the polishing liquid of Example 1 was 3.26, the pH of the polishing liquid of Example 2 was 3.19, the pH of the polishing liquid of Example 3 was 4.00, and the pH of the polishing liquid of Example 4 was 4.54.

### <Measurement of Average Particle Diameter>

An average particle diameter D50 of the colloidal ceria particles in the polishing liquid was determined using “Microtrac MT3300 EXII” manufactured by MicrotracBEL Corp. The measurement results are shown in Table 1.

### <Polishing Evaluation>

In a polishing apparatus (trade name: Mirra3400, manufactured by APPLIED MATERIALS Inc.), a substrate having a film to be polished (silicon oxide film (TEOS film) or silicon nitride film (SiN film)) formed on a φ200 mm silicon wafer was set in a holder for attaching a substrate to which an adsorption pad was attached. The holder was placed on a platen to which a porous urethane resin pad was attached so that the film to be polished faced the pad. The substrate was pressed against the pad with a polishing load of 20 kPa while each of the polishing liquids described above was supplied onto the pad at a supply amount of 200 mL/min. At this time, polishing was performed by rotating the platen at 93 min⁻¹ and the holder at 87 min⁻¹ for 30 seconds. The substrate after polishing was thoroughly washed with pure water and then dried. A film thickness change before and after polishing of the film to be polished was measured using a light interference type film thickness measuring apparatus to determine a polishing rate (TEOS RR and SiN RR, unit: Å/min). In addition, a polishing rate ratio of silicon oxide to silicon nitride (polishing rate for silicon oxide/polishing rate for silicon nitride) was determined. The results are shown in Table 1.

TABLE 1

| | | | Polishing rate | | Polishing |
|---|---|---|---|---|---|
| | | D50 | [nm/min] | | rate ratio |
| | Additive | [nm] | SiO₂ | SiN | SiO₂/SiN |
| Example 1 | Ethoxyacetic acid | 144 | 25 | 1 | 25 |
| Example 2 | Methoxyacetic acid | 143 | 33 | 2 | 16 |
| Example 3 | Ethoxyacetic acid | Unmeasured | 357 | 3 | 119 |
| Example 4 | Ethoxyacetic acid | Unmeasured | 368 | 34 | 11 |
| Comparative | Not used | 141 | 408 | 76 | 5 |
| Example 1 | | | | | |
| Comparative | β-Alanine | 142 | 430 | 79 | 5 |
| Example 2 | | | | | |
| Comparative | 2-Hydroxyisobutyric acid | 140 | 455 | 2 | 253 |
| Example 3 | | | | | |
| Comparative | Picolinic acid | 138 | 428 | 2 | 214 |
| Example 4 | | | | | |
| Comparative | Acetic acid | 146 | 470 | 4 | 107 |
| Example 5 | | | | | |
| Comparative | Propionic acid | 143 | 546 | 3 | 210 |
| Example 6 | | | | | |
| Comparative | 2,2-Bis(hydroxymethyl)butyric acid | 147 | 459 | 1 | 383 |
| Example 7 | | | | | |
| Comparative | 2,2-Bis(hydroxymethyl)propionic | 146 | 468 | 2 | 223 |
| Example 8 | acid | | | | |

1. A polishing liquid comprising: abrasive grains; an ether compound having at least one selected from the group consisting of a carboxy group and a carboxylate group; and
water.

2. The polishing liquid according to claim 1, wherein the abrasive grains contain cerium oxide.

3. The polishing liquid according to claim 1, wherein the ether compound comprises a compound represented by the following General Formula (1): 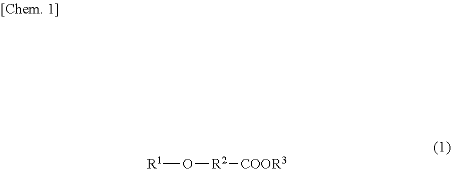
wherein R¹ represents an alkyl group having 1 to 10 carbon atoms, R² represents an alkylene group having 1 to 10 carbon atoms, and R³ represents a hydrogen atom or a monovalent metal atom.

4. The polishing liquid according to claim 1, wherein the ether compound comprises at least one selected from the group consisting of ethoxyacetic acid, methoxyacetic acid, and salts thereof.

5. The polishing liquid according to claim 1, wherein a content of the ether compound is less than 0.10 mass % based on a total mass of the polishing liquid.

6. The polishing liquid according to claim 1, wherein a pH is 2.0 to 5.0.

7. The polishing liquid according to claim 1, wherein the polishing liquid is used for polishing a surface to be polished comprising silicon oxide.

8. A polishing liquid set comprising constituent components of the polishing liquid according to claim 1 separately stored in a first liquid and a second liquid, wherein the first liquid comprises the abrasive grains and water, and the second liquid comprises the ether compound and water.

9. A polishing method comprising a step of polishing a surface to be polished comprising silicon oxide using the polishing liquid according to claim 1.

10. A polishing method comprising a step of polishing a surface to be polished comprising silicon oxide using a polishing liquid obtained by mixing the first liquid and the second liquid in the polishing liquid set according to claim 8.
